(19) United States
(12) Patent Application Publication
(10) Pub. No.: US 2026/0101584 A1
(43) Pub. Date: Apr. 9, 2026

(54) ARRAY SUBSTRATE AND PREPARATION METHOD THEREFOR, AND DISPLAY PANEL

(71) Applicants: Hefei Visionox Technology Co., Ltd., Hefei (CN); Visionox Technology Inc., Kunshan (CN)

(72) Inventors: Guowen YAN, Hefei (CN); Dejian WANG, Hefei (CN); Lidong DING, Kunshan (CN); Fa-Hsyang CHEN, Kunshan (CN)

(73) Assignees: Hefei Visionox Technology Co., Ltd., Hefei (CN); Visionox Technology Inc., Kunshan (CN)

(21) Appl. No.: 19/387,525

(22) Filed: Nov. 12, 2025

(30) Foreign Application Priority Data
Nov. 15, 2024 (CN) 202411634934.0

(51) Int. Cl. H10D 86/40; H10D 86/01

(52) U.S. Cl. CPC H10D 86/423; H10D 86/0221; H10D 86/431

(57) ABSTRACT

Embodiments of the present application provide an array substrate and a preparation method therefor, and a display panel. The array substrate includes: a substrate; a first semiconductor layer located on one side of the substrate, the first semiconductor layer including a first active portion; a first insulating layer located on a side of the first semiconductor layer facing away from the substrate; a second semiconductor layer located on a side of the first insulating layer facing away from the first semiconductor layer, the second semiconductor layer including a second active portion; wherein a carrier mobility of one of the first active portion and the second active portion is greater than that of the other.

### CROSS-REFERENCE TO RELATED APPLICATIONS

The present application claims priority to Chinese Patent Application No. 202411634934.0, entitled “ARRAY SUBSTRATE AND PREPARATION METHOD THEREFOR, AND DISPLAY PANEL” and filed on Nov. 15, 2024, which is incorporated herein by reference in its entirety.

### FIELD

The present application relates to the field of display devices, and in particular, to an array substrate and a preparation method therefor, and a display panel.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

However, the process performance of conventional OLED display products needs to be improved.

### SUMMARY

Embodiments of the present application provide an array substrate and a preparation method therefor, and a display panel, with the aim of improving process performance of the array substrate.

An embodiment of a first aspect of the present application provides an array substrate. The array substrate includes: a substrate; a first semiconductor layer located on one side of the substrate, the first semiconductor layer including a first active portion; a first insulating layer located on a side of the first semiconductor layer facing away from the substrate; a second semiconductor layer located on a side of the first insulating layer facing away from the substrate, the second semiconductor layer including a second active portion; a first gate located on the side of the first semiconductor layer facing away from the substrate, where an orthographic projection of the first gate on the substrate at least partially overlaps an orthographic projection of the first active portion on the substrate; and a second gate located on a side of the second semiconductor layer facing away from the substrate, where an orthographic projection of the second gate on the substrate at least partially overlaps an orthographic projection of the second active portion on the substrate, where a carrier mobility of one of the first active portion and the second active portion is greater than that of the other.

An embodiment of a first aspect of the present application provides an array substrate. The array substrate includes: a substrate; a first semiconductor layer located on one side of the substrate, the first semiconductor layer including a first active portion; a first insulating layer located on a side of the first semiconductor layer facing away from the substrate; a second semiconductor layer located on a side of the first insulating layer facing away from the substrate, the second semiconductor layer including a second active portion; a first gate located on the side of the first semiconductor layer facing away from the substrate, where an orthographic projection of the first gate on the substrate at least partially overlaps an orthographic projection of the first active portion on the substrate; and a second gate located on a side of the second semiconductor layer facing away from the substrate, where an orthographic projection of the second gate on the substrate at least partially overlaps an orthographic projection of the second active portion on the substrate, where a material of each of the first active portion and the second active portion includes indium, and an indium content of one of the first active portion and the second active portion is greater than that of the other.

An embodiment in a second aspect of the present application further provides a preparation method for an array substrate. The method includes:
disposing a first active material layer on one side of a substrate, and patterning the first active material layer to form a first semiconductor layer having a first active portion;
disposing a first insulating layer on a side of the first semiconductor layer facing away from the substrate;
disposing a second active material layer on a side of the first insulating layer facing away from the substrate, and patterning the second active material layer to form a second semiconductor layer having a second active portion; and
preparing a first gate and a second gate on a side of the second semiconductor layer facing away from the substrate, where an orthographic projection of the first gate on the substrate at least partially overlaps an orthographic projection of the first active portion on the substrate, and an orthographic projection of the second gate on the substrate at least partially overlaps an orthographic projection of the second active portion on the substrate,
where a carrier mobility of one of the first active portion and the second active portion is greater than that of the other.

A third aspect of the present application further provides a display panel. The display panel includes the array substrate according to any one of the embodiments of the first aspect described above, or the array substrate prepared according to the preparation method of any one of the second aspects described above.

### BRIEF DESCRIPTION OF THE DRAWINGS

By reading the following detailed description of non-limiting embodiments made with reference to the drawings, the embodiments of the present application will become more apparent, in which the same or similar features are denoted by the same or similar reference signs.

FIG. 1 is a schematic structural diagram of an array substrate according to an embodiment of the present application;

FIG. 2 is a cross-sectional view taken along A-A in FIG. 1 according to an embodiment of the present application;

FIG. 3 is a cross-sectional view taken along A-A in FIG. 1 according to another embodiment of the present application;

FIG. 4 is a cross-sectional view taken along A-A in FIG. 1 according to still another embodiment of the present application;

FIG. 5 is a cross-sectional view taken along A-A in FIG. 1 according to yet another embodiment of the present application;

FIG. 6 is a cross-sectional view taken along A-A in FIG. 1 according to still yet another embodiment of the present application;

FIG. 7 is a structural diagram of a pixel circuit of an array substrate according to an embodiment of the present application;

FIG. 8 is a schematic flowchart of a preparation method for an array substrate according to an embodiment of the present application;

FIGS. 9 to 12 are schematic structural diagrams of a process of a preparation method for an array substrate according to an embodiment of the present application;

FIG. 13 is a schematic flowchart of a preparation method for an array substrate according to another embodiment of the present application; and

FIGS. 14 and 15 are schematic structural diagrams of a process of a preparation method for an array substrate according to another embodiment of the present application.

List of reference signs:
100. Substrate;
20a. First semiconductor layer; 210. First active portion; 211. First sub-layer; 211a. First outer edge sub-layer; 211b. First inner edge sub-layer; 211c. First intermediate layer; 212. First source region; 213. First drain region; 214. First channel region; 20b. Second semiconductor layer; 220. Second active portion; 221. Second sub-layer; 221a. Second outer edge sub-layer; 221b. Second inner edge sub-layer; 221c. Second intermediate layer; 222. Second source region; 223. Second drain region; 224. Second channel region; 310. First insulating layer; 311. Third section; 312. Fourth section; 320. Second insulating layer; 321: First section; 322: Second section; 330. Third insulating layer; 340. Fourth insulating layer;
410. First gate; 420. Second gate; 430. Third gate; 440. Fourth gate;
510. First source; 520. First drain; 530. Second source; 540. Second drain;
T1. First transistor; and T2. Second transistor.

### DETAILED DESCRIPTION OF THE EMBODIMENTS

The features and exemplary embodiments of the present application in various aspects are described in detail below. In the following detailed description, many specific details are set forth to comprehensively understand the present application. However, it will be very apparent t that the present application may be implemented without some of these specific details. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures, or characteristics described below may be combined, in any suitable manner, in one or more embodiments.

In the description of the present application, it should be noted that “a plurality of” means two or more, unless otherwise specified. The orientation or position relationship indicated by the terms “upper”, “lower”, “left”, “right”, “inner”, “outer”, etc. is merely for the convenience of describing the present application and simplifying the description, rather than indicating or implying that a device or element referred to must have a particular orientation or be constructed and operated in a particular orientation, and therefore should not be construed as limiting the present application. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the present application. In the description of the present application, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection. The specific meanings of the terms mentioned above in the present application may be construed according to specific circumstances.

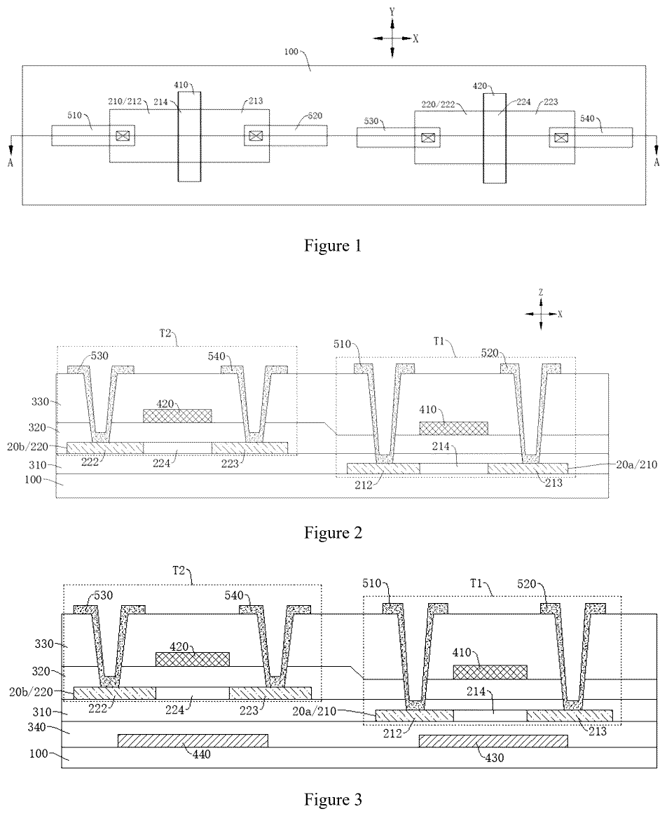

Referring to FIGS. 1 and 2 together, FIG. 1 is a partial cross-sectional view of an array substrate according to an embodiment of the present application, and FIG. 2 is a cross-sectional view taken along A-A in FIG. 1 according to an example.

As shown in FIG. 1 and FIG. 2, an embodiment of a first aspect of the present application provides an array substrate. The array substrate includes: a substrate 100; a first semiconductor layer 20a located on one side of the substrate 100, the first semiconductor layer including a first active portion 210; a first insulating layer 310 located on a side of the first semiconductor layer 20a facing away from the substrate 100; a second semiconductor layer 20b located on a side of the first insulating layer 310 facing away from the substrate 100, the second semiconductor layer 20b including a second active portion 220; a first gate 410 located on a side of the first semiconductor layer 20a facing away from the substrate 100, where an orthographic projection of the first gate 410 on the substrate 100 at least partially overlaps an orthographic projection of the first active portion 210 on the substrate 100; and a second gate 420 located on a side of the second semiconductor layer 20b facing away from the substrate 100, where an orthographic projection of the second gate 420 on the substrate 100 at least partially overlaps an orthographic projection of the second active portion 220 on the substrate 100, where a carrier mobility of one of the first active portion 210 and the second active portion 220 is greater than that of the other.

In the array substrate provided in the embodiments of the present application, the array substrate includes the substrate 100, the first semiconductor layer 20a, the first insulating layer 310, the second semiconductor layer 20b, the first gate 410, and the second gate 420. The orthographic projection of the first gate 410 on the substrate 100 at least partially overlaps the orthographic projection of the first active portion 210 of the first semiconductor layer 20a on the substrate 100. The first gate 410 is disposed corresponding to the first active portion 210 to turn on the first active portion 210. Likewise, the second gate 420 is disposed corresponding to the second active portion 220 to turn on the second active portion 220. A carrier mobility of one of the first active portion 210 and the second active portion 220 is greater than that of the other, that is, the first active portion 210 and the second active portion 220 have different carrier mobilities. The first insulating layer 310 is disposed between the first semiconductor layer 20a where the first active portion 210 is located and the second semiconductor layer 20b where the second active portion 220 is located, to facilitate adjustment of carrier concentration in the first active portion 210 by using the first insulating layer 310, thereby achieving process compatibility between the first active portion 210 and the second active portion 220, and thus improving process performance of the array substrate.

In some embodiments, the array substrate includes a first transistor T1 and a second transistor T2, the first transistor T1 includes a first source 510, a first drain 520, the first active portion 210, and the first gate 410, and the second transistor T2 includes a second source 530, a second drain 540, the second active portion 220, and the second gate 420. That is, the first source 510, the first drain 520, the first gate 410, and the first active portion 210 together form the first transistor T1; and the second source 530, the second drain 540, the second gate 420, and the second active portion 220 together form the second transistor T2.

In some embodiments, the first active portion 210 includes a first source region 212, a first drain region 213, and a first channel region 214 located between the first source region 212 and the first drain region 213. The first source 510 is electrically connected to the first source region 212, the first drain region 213 is electrically connected to the first drain 520, and the orthographic projection of the first gate 410 on the substrate 100 at least partially overlaps an orthographic projection of the first channel region 214 on the substrate 100. The first gate 410 is configured to control an on/off state of the first channel region 214. When the first channel region 214 is turned on, the first source 510 and the first drain 520 are electrically connected to each other through the first active portion 210. When the first channel region 214 is turned off, the first source 510 and the first drain 520 are disconnected from each other.

In some embodiments, the second active portion 220 includes a second source region 222, a second drain region 223, and a second channel region 224 located between the second source region 222 and the second drain region 223. The second source 530 is electrically connected to the second source region 222, the second drain region 223 is electrically connected to the second drain 540, and the orthographic projection of the second gate 420 on the substrate 100 at least partially overlaps an orthographic projection of the second channel region 224 on the substrate 100. The second gate 420 is configured to control an on/off state of the second channel region 224. When the second channel region 224 is turned on, the second source 530 and the second drain 540 are electrically connected to each other through the second active portion 220. When the second channel region 224 is turned off, the second source 530 and the second drain 540 are disconnected from each other.

In some embodiments, the first transistor T1 and the second transistor T2 are transistors having different mobilities. When no first insulating layer 310 is disposed between the first active portion 210 and the second active portion 220, under a same process condition, a difference in threshold voltages between the first transistor T1 and the second transistor T2 may be too large. When a threshold-voltage requirement of a low-mobility transistor is met, a high-mobility transistor may be severely negatively biased, failing to meet a circuit requirement. In one embodiment, when a threshold-voltage requirement of the high-mobility transistor is met, stability of the low-mobility transistor may be affected.

In the embodiment of the present application, since the first insulating layer 310 is disposed between the first active portion 210 and the second active portion 220, the first insulating layer 310 can adjust carriers in the semiconductor layer that are located on a side of the first insulating layer 310 facing the substrate 100, thereby making the difference in threshold voltages between the first transistor T1 and the second transistor T2 within a reasonable range, and thus achieving the process compatibility of the first transistor T1 and the second transistor T2.

In some embodiments, a thickness of the first insulating layer 310 is 10 nm to 200 nm. This can improve the situation where the first insulating layer 310 has an excessively small thickness and the carriers in the first active portion 210 cannot be properly adjusted, and can also improve the situation where the first insulating layer 310 has an excessively large thickness to cause material waste, thereby avoiding an increase in an overall thickness of the array substrate.

In some embodiments, the thickness of the first insulating layer 310 may be 10 nm, 23 nm, 58 nm, 69 nm, 140 nm, 185 nm, 200 nm, etc.

For example, the thickness of the first insulating layer 310 may be 50 nm to 100 nm. In this way, it can be ensured that the first insulating layer 310 has a sufficient thickness and the carriers in the first active portion 210 can be adjusted, and the situation where the first insulating layer 310 has an excessively large thickness to cause material waste can be improved.

In some embodiments, the thickness of the first insulating layer 310 may be 50 nm, 53 nm, 58 nm, 69 nm, 80 nm, 85 nm, 100 nm, etc.

The first insulating layer 310 may be made of various materials. For example, a material of the first insulating layer 310 may include at least one of silicon oxide, silicon nitride, or silicon oxynitride. A hydrogen content and oxygen content of the first insulating layer 310 may be adjusted to adjust the carriers in the first active portion 210, to adjust a threshold voltage of the first transistor T1.

In some embodiments, a carrier mobility of the first active portion 210 is less than that of the second active portion 220, and each of a material of the first active portion 210 and the second active portion 220 includes metal oxide. Then the first transistor T1 may be a low-mobility transistor, and the second transistor T2 may be a high-mobility transistor.

In some embodiments, the metal oxide includes indium oxide (In oxide), indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, abbreviated as IGTO), gallium zinc oxide (Ga—Zn oxide, abbreviated as GZO), aluminum zinc oxide (Al—Zn oxide, abbreviated as AZO), indium aluminum zinc oxide (In—Al—Zn oxide, abbreviated as IAZO), indium tin zinc oxide (In—Sn—Zn oxide, abbreviated as ITZO), indium titanium zinc oxide (In—Ti—Zn oxide), indium gallium zinc oxide (In—Ga—Zn oxide, abbreviated as IGZO), indium gallium tin zinc oxide (In—Ga—Sn—Zn oxide, abbreviated as IGZTO), indium gallium aluminum zinc oxide (In—Ga—Al—Zn oxide, abbreviated as IGAZO, IGZAO, or IAGZO), gallium tin oxide (Ga—Sn oxide), and aluminum tin oxide (Al—Sn oxide), etc.

In some embodiments, when the carrier mobility of the first active portion 210 is less than that of the second active portion 220, the material of the first active portion 210 may include at least one of indium oxide, gallium oxide, zinc oxide, tin oxide, indium gallium zinc oxide, or indium gallium oxide, where a number of indium atoms accounts for 30% to 70% of a total number of metal atoms in the first active portion 210, a number of gallium atoms accounts for 0 to 70% of the total number of metal atoms in the first active portion 210, and a number of zinc atoms accounts for 0 to 70% of the total number of metal atoms in the first active portion 210.

In these embodiments, the number of indium atoms in the first active portion 210 accounts for 30% to 70% of the total number of metal atoms in the first active portion 210. An atomic percentage of indium in the first active portion 210 is relatively low, and the first active portion 210 has a relatively low carrier mobility.

As an embodiment, atomic percentages of indium, gallium, and zinc in the first active portion 210 may be 30%, 0%, and 70%, respectively, or the atomic percentages of indium, gallium, and zinc in the first active portion 210 may be 30%, 70%, and 0, respectively, or the atomic percentages of indium, gallium, and zinc in the first active portion 210 may be 30%, 35%, and 35%, respectively, or the atomic percentages of indium, gallium, and zinc in the first active portion 210 may be 35%, 5%, and 60%, respectively, or the atomic percentages of indium, gallium, and zinc in the first active portion 210 may be 70%, 25%, 5%, respectively, etc., as long as a sum of the atomic percentages of indium, gallium, and zinc in the first active portion 210 is less than or equal to 100%.

In some embodiments, the thickness of the first active portion 210 ranges from 3 nm to 100 nm. This can improve the situation where the first active portion 210 has an excessively small thickness and movement of carriers in the first active portion 210 is affected, and can also improve the situation where the first active portion 210 has an excessively large thickness, resulting in material waste and failure of the first transistor T1 in meeting usage requirements.

For example, the thickness of the first active portion 210 may be 3 nm, 5 nm, 18 nm, 55 nm, 70 nm, 90 nm, 100 nm, etc.

In some embodiments, when the carrier mobility of the first active portion 210 is less than that of the second active portion 220, the material of the second active portion 220 includes at least one of indium oxide, gallium oxide, zinc oxide, tin oxide, indium gallium zinc oxide, or indium gallium oxide, where a number of indium atoms accounts for 50% to 100% of a total number of metal atoms in the second active portion 220, a number of gallium atoms accounts for 0 to 50% of the total number of metal atoms in the second active portion 220, and a number of zinc atoms accounts for 0 to 50% of the total number of metal atoms in the second active portion 220.

In these embodiments, an atomic percentage of indium in the second active portion 220 is relatively high, and the second active portion 220 has a relatively high carrier mobility.

As an embodiment, atomic percentages of indium, gallium, and zinc in the second active portion 220 may be 100%, 0, and 0, respectively, or the atomic percentages of indium, gallium, and zinc in the second active portion 220 may be 90%, 10%, and 0, respectively, or the atomic percentages of indium, gallium, and zinc in the second active portion 220 may be 90%, 0%, and 10%, respectively, or the atomic percentages of indium, gallium, and zinc in the second active portion 220 may be 80%, 10%, and 10%, respectively, or the atomic percentages of indium, gallium, and zinc in the second active portion 220 may be 50%, 35%, 15%, respectively, etc., as long as a sum of the atomic percentages of indium, gallium, and zinc in the second active portion 220 is less than or equal to 100%.

In some embodiments, the thickness of the second active portion 220 ranges from 3 nm to 100 nm. This can improve the situation where the second active portion 220 has an excessively small thickness and movement of carriers in the second active portion 220 is affected, and can also improve the situation where the second active portion 220 has an excessively large thickness, resulting in material waste and failure of the second transistor T2 in meeting usage requirements.

For example, the thickness of the second active portion 220 may be 3 nm, 5 nm, 18 nm, 55 nm, 70 nm, 90 nm, 100 nm, etc.

In some embodiments, when the carrier mobility of the first active portion 210 is less than that of the second active portion 220, a metallic atomic percentage of indium in the first active portion 210 is less than that of indium in the second active portion 220, and the carrier mobility of the first active portion 210 is less than that of the second active portion 220. For example, when the number of indium atoms in the second active portion 220 accounts for 50% of the total number of metal atoms in the second active portion 220, the number of indium atoms in the first active portion 210 accounts for 49%, 40%, etc. of the total number of metal atoms in the first active portion 210; when the number of indium atoms in the second active portion 220 accounts for 80% of the total number of metal atoms in the second active portion 220, the number of indium atoms in the first active portion 210 accounts for 79%, 40%, etc. of the total number of metal atoms in the first active portion 210, as long as the atomic percentage of indium in the first active portion 210 is less than that of indium in the second active portion 220.

In some other embodiments, a carrier mobility of the first active portion 210 may alternatively be greater than that of the second active portion 220, and a material of the first active portion 210 and/or the second active portion 220 includes metal oxide. Then the first transistor T1 may be a high-mobility transistor, and the second transistor T2 may be a low-mobility transistor.

In some embodiments, the metal oxide includes indium oxide (In oxide), indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, abbreviated as IGTO), gallium zinc oxide (Ga—Zn oxide, abbreviated as GZO), aluminum zinc oxide (Al—Zn oxide, abbreviated as AZO), indium aluminum zinc oxide (In—Al—Zn oxide, abbreviated as IAZO), indium tin zinc oxide (In—Sn—Zn oxide, abbreviated as ITZO), indium titanium zinc oxide (In—Ti—Zn oxide), indium gallium zinc oxide (In—Ga—Zn oxide, abbreviated as IGZO), indium gallium tin zinc oxide (In—Ga—Sn—Zn oxide, abbreviated as IGZTO), indium gallium aluminum zinc oxide (In—Ga—Al—Zn oxide, abbreviated as IGAZO, IGZAO, or IAGZO), gallium tin oxide (Ga—Sn oxide), and aluminum tin oxide (Al—Sn oxide), etc.

In some embodiments, when the carrier mobility of the first active portion 210 is greater than that of the second active portion 220, the material of the second active portion 220 may include at least one of indium oxide, gallium oxide, zinc oxide, tin oxide, indium gallium zinc oxide, or indium gallium oxide, where a number of indium atoms accounts for 30% to 70% of a total number of metal atoms in the second active portion 220, a number of gallium atoms accounts for 0 to 70% of the total number of metal atoms in the second active portion 220, and a number of zinc atoms accounts for 0 to 70% of the total number of metal atoms in the second active portion 220.

In these embodiments, the number of indium atoms in the second active portion 220 accounts for 30% to 70% of the total number of metal atoms in the second active portion 220. An atomic percentage of indium in the second active portion 220 is relatively low, and the second active portion 220 has a relatively low carrier mobility.

As an embodiment, the atomic percentages of indium, gallium, and zinc in the second active portion 220 may be 30%, 0, and 70%, respectively, or the atomic percentages of indium, gallium, and zinc in the second active portion 220 may be 30%, 70%, and 0, respectively, or the atomic percentages of indium, gallium, and zinc in the second active portion 220 may be 30%, 35%, and 35%, respectively, or the atomic percentages of indium, gallium, and zinc in the second active portion 220 may be 35%, 5%, and 60%, respectively, or the atomic percentages of indium, gallium, and zinc in the second active portion 220 may be 70%, 25%, 5%, respectively, etc., as long as the sum of the atomic percentages of indium, gallium, and zinc in the second active portion 220 is less than or equal to 100%.

In some embodiments, the manner in which the thicknesses of the first active portion 210 and the second active portion 220 are set is described above, which will not be repeated here.

In some embodiments, when the carrier mobility of the first active portion 210 is greater than that of the second active portion 220, the material of the first active portion 210 includes at least one of indium oxide, gallium oxide, zinc oxide, tin oxide, indium gallium zinc oxide, or indium gallium oxide, where a number of indium atoms accounts for 50% to 100% of a total number of metal atoms in the first active portion 210, a number of gallium atoms accounts for 0 to 50% of the total number of metal atoms in the first active portion 210, and a number of zinc atoms accounts for 0 to 50% of the total number of metal atoms in the first active portion 210.

In these embodiments, the metallic atomic percentage of indium in the first active portion 210 is relatively high, and the first active portion 210 has a relatively high carrier mobility.

As an embodiment, the atomic percentages of indium, gallium, and zinc in the first active portion 210 may be 100%, 0, and 0, respectively, or the atomic percentages of indium, gallium, and zinc in the first active portion 210 may be 90%, 10%, and 0, respectively, or the atomic percentages of indium, gallium, and zinc in the first active portion 210 may be 90%, 0%, and 10%, respectively, or the atomic percentages of indium, gallium, and zinc in the first active portion 210 may be 80%, 10%, and 10%, respectively, or the atomic percentages of indium, gallium, and zinc in the first active portion 210 may be 50%, 35%, 15%, respectively, etc., as long as the sum of the atomic percentages of indium, gallium, and zinc in the first active portion 210 is less than or equal to 100%.

In some embodiments, when the carrier mobility of the first active portion 210 is greater than that of the second active portion 220, a metallic atomic percentage of indium in the first active portion 210 is greater than that of indium in the second active portion 220, and the carrier mobility of the first active portion 210 is greater than that of the second active portion 220.

In some embodiments, continuing to refer to FIG. 1 and FIG. 2, the array substrate further includes a second insulating layer 320. The second insulating layer 320 is located on the side of the second semiconductor layer 20b facing away from the substrate 100, and the second gate 420 is located on a side of the second insulating layer 320 facing away from the substrate 100. The second insulating layer 320 is disposed to achieve mutual insulation between the second gate 420 and the second semiconductor layer 20b.

The second insulating layer 320 may be made of various materials. For example, a material of the second insulating layer 320 may include at least one of silicon oxide, silicon nitride, or silicon oxynitride. A hydrogen content and oxygen content of the second insulating layer 320 may be adjusted to adjust the carriers in the second active portion 220, to adjust a threshold voltage of the second transistor T2.

The first insulating layer 310 and/or the second insulating layer 320 may be configured in various ways. In one embodiment, as shown in FIG. 2 and FIG. 3, the first insulating layer 310 may be provided as a continuous layer, that is, the first insulating layer 310 is deposited as a continuous layer on the side of the first semiconductor layer 20a facing away from the substrate 100. No patterning is performed on the first insulating layer 310, except for providing necessary vias on the first insulating layer 310 to achieve electrical connection between the first source 510, the first drain 520, and the first active portion 210. In one embodiment, the second insulating layer 320 may also be provided as a continuous layer.

In some embodiments, the first insulating layer 310 is in contact with the first active portion 210 and the second active portion 220. That is, the first insulating layer 310 is located between the first semiconductor layer 20a and the second semiconductor layer 20b, and no other layer structure is disposed between the first semiconductor layer 20a and the second semiconductor layer 20b, and the first insulating layer 310 is in contact with the first active portion 210 and the second active portion 220.

In some embodiments, the second insulating layer 320 is in contact with the second active portion 220. That is, in a preparation process, after the second active portion 220 is disposed, the second insulating layer 320 is immediately prepared on the second active portion 220, and the second insulating layer 320 can be in direct contact with the second active portion 220.

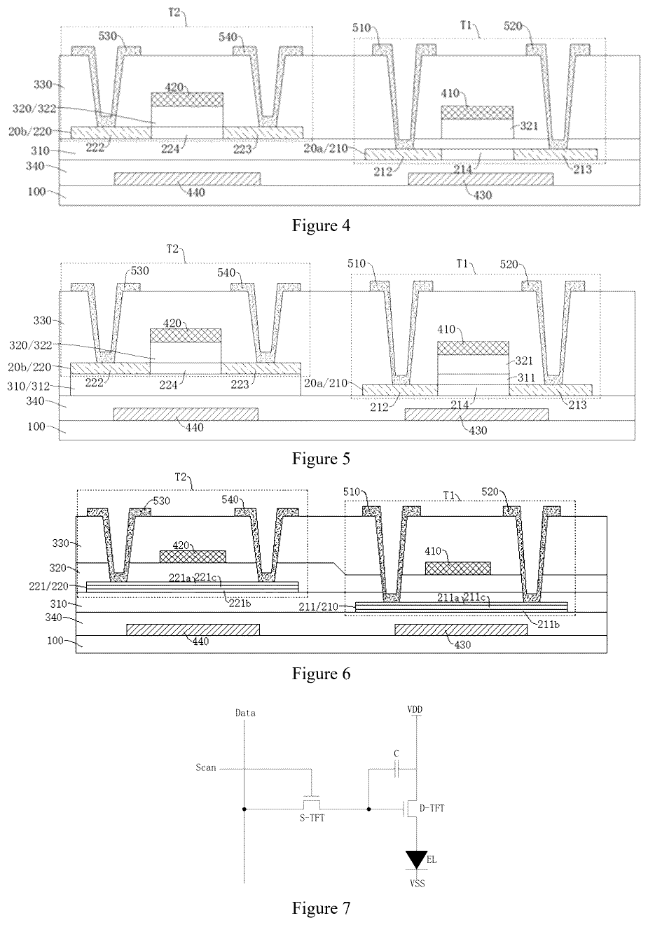

In some other embodiments, as shown in FIG. 4, the first insulating layer 310 and/or the second insulating layer 320 may be provided as a non-continuous layer. For example, the second insulating layer 320 includes a first section 321 located on a side of the first gate 410 facing the substrate 100 and a second section 322 located on a side of the second gate 420 facing the substrate 100, and the first section 321 and the second section 322 are spaced apart.

In these embodiments, the second insulating layer 320 is patterned to form the first section 321 and the second section 322, allowing the second insulating layer 320 to not only play a role in insulation but also reduce an overall distribution area of the second insulating layer 320, which simplifies a structure of the array substrate. This allows a portion of thickness of the array substrate to be reduced, further facilitating bending.

In some embodiments, an orthographic projection of the first section 321 on the substrate 100 overlaps an orthographic projection of the first gate 410 on the substrate 100. In the preparation process of the array substrate, the first gate 410 may be used as a mask to pattern the second insulating layer 320 to form the first section 321, without adding a new mask, thereby simplifying the preparation process.

In some embodiments, an orthographic projection of the second section 322 on the substrate 100 overlaps an orthographic projection of the second gate 420 on the substrate 100. In the preparation process of the array substrate, the second gate 420 may be used as a mask to pattern the second insulating layer 320 to form the second section 322, without adding a new mask, thereby simplifying the preparation process.

In some embodiments, when the second insulating layer 320 includes the first section 321 and the second section 322, as shown in FIG. 4, the first insulating layer 310 may be provided as a continuous layer, or, as shown in FIG. 5, the first insulating layer 310 may be provided as a non-continuous layer.

In some embodiments, as shown in FIG. 5, the first insulating layer 310 includes a third section 311 located on a side of the first section 321 facing the substrate 100 and a fourth section 312 located on a side of the second active portion 220 facing the substrate 100, and the third section 311 and the fourth section 312 are spaced apart.

In these embodiments, the first insulating layer 310 is patterned to form the third section 311 and the fourth section 312, allowing the first insulating layer 310 to not only play a role in but also reduce an overall distribution area of the first insulating layer 310, which simplifies a structure of the array substrate.

In some embodiments, an orthographic projection of the third section 311 on the substrate 100 overlaps an orthographic projection of the first section 321 on the substrate 100. In the preparation process of the array substrate, the first gate 410 may be used as a mask to pattern the second insulating layer 320 to form the first section 321, and pattern the first insulating layer 310 to form the third section 311, without adding a new mask, thereby simplifying the preparation process. Moreover, the third section 311 and the first section 321 may be prepared and formed in the same process step, which can simplify the preparation process of the array substrate.

In one embodiment, an orthographic projection of the fourth section 312 on the substrate 100 overlaps the orthographic projection of the second active portion 220 on the substrate 100. In the preparation process of the array substrate, the second active portion 220 may be used as a mask to pattern the first insulating layer 310 to form the fourth section 312, without adding a new mask, thereby simplifying the preparation process.

In the preparation process of the first insulating layer 310 and the second insulating layer 320, after the first gate 410 and the second gate 420 are prepared, the first gate 410 and the second gate 420 may be used as masks to pattern the first insulating layer 310 and the second insulating layer 320 to form the first section 321, the second section 322, and the third section 311. The fourth section 312 is formed due to shielding of the second active portion 220.

The first active portion 210 may be configured in various ways. As shown in FIG. 1 to FIG. 5, the first active portion 210 may be provided as a single layer or a stacked layer. When the first active portion 210 is a single layer, the carrier mobility of the first active portion 210 is greater than or less than that of the second active portion 220.

In one embodiment, as shown in FIG. 6, when the first active portion 210 is a stacked layer and includes a plurality of first sub-layers 211 that are disposed in a stacked manner, a carrier mobility of each of the first sub-layers 211 is greater than or less than that of the second active portion 220.

In some embodiments, the first sub-layers 211 are stacked to form the first source region 212, the first drain region 213, and the first channel region 214.

A number of the first sub-layers 211 may be configured in various ways. There may be two first sub-layers 211, and the two first sub-layers 211 may have different carrier mobilities to adjust an overall carrier mobility of the first active portion 210 within an appropriate range.

In one embodiment, there may be three first sub-layers 211, and a carrier mobility of the first sub-layer 211 located in the middle is greater than those of the other first sub-layers 211. The first sub-layer 211 in the middle has the highest carrier mobility, which can enhance transport efficiency of carriers and ensure performance of the first active portion 210.

In some embodiments, when there are three or more first sub-layers 211, a plurality of first sub-layers 211 may include a first outer edge sub-layer 211a, a first inner edge sub-layer 211b, and a first intermediate sub-layer 211c, and the first outer edge sub-layer 211a is located on a side of the first intermediate sub-layer 211c facing away from the substrate 100, the first inner edge sub-layer 211b is located on a side of the first intermediate sub-layer 211c facing the substrate 100, and carrier mobilities of the first outer edge sub-layer 211a and the first inner edge sub-layer 211b are both less than that of the first intermediate sub-layer 211c.

In still some embodiments, there may be four or more first sub-layers 211, and the four or more first sub-layers 211 include the first outer edge sub-layer 211a, the first inner edge sub-layer 211b, and the first intermediate sub-layer 211c, and any of the first sub-layers 211 located between the first outer edge sub-layer 211a and the first inner edge sub-layer 211b may be the first intermediate sub-layer 211c.

The second active portion 220 may be configured in various ways. As shown in FIG. 1 to FIG. 5, the second active portion 220 may be provided as a single layer or a stacked layer. When the second active portion 220 is a single layer, the carrier mobility of the second active portion 220 is greater than or less than that of the first active portion 210

In one embodiment, as shown in FIG. 6, when the second active portion 220 is a stacked layer and includes a plurality of second sub-layers 221 that are disposed in a stacked manner, a carrier mobility of each of the second sub-layers 221 is greater than or less than that of the first active portion 210.

A number of the second sub-layers 221 may be configured in various ways. There may be two second sub-layers 221, and the two second sub-layers 221 may have different carrier mobilities to adjust an overall carrier mobility of the second active portion 220 within an appropriate range.

In one embodiment, there may be three second sub-layers 221, and a carrier mobility of the second sub-layer 221 located in the middle is greater than those of the other second sub-layers 221. The second sub-layer 221 in the middle has the highest carrier mobility, which can enhance transport efficiency of carriers and ensure performance of the second active portion 220.

In some embodiments, when there are three or more second sub-layers 221, a plurality of second sub-layers 221 may include a second outer edge sub-layer 221a, a second inner edge sub-layer 221b, and a second intermediate sub-layer 221c, and the second outer edge sub-layer 221a is located on a side of the second intermediate sub-layer 221c facing away from the substrate 100, the second inner edge sub-layer 221b is located on a side of the second intermediate sub-layer 221c facing the substrate 100, and carrier mobilities of the second outer edge sub-layer 221a and the second inner edge sub-layer 221b are both less than that of the second intermediate sub-layer 221c.

In still some embodiments, there may be four or more second sub-layers 221, and the four or more second sub-layers 221 include the second outer edge sub-layer 221a, the second inner edge sub-layer 221b, and the second intermediate sub-layer 221c, and any of the second sub-layers 221 located between the second outer edge sub-layer 221a and the second inner edge sub-layer 221b may be the second intermediate sub-layer 221c.

In some embodiments, when the array substrate includes the first transistor T1 and the second transistor T2, an absolute value of a difference in threshold voltages between the first transistor T1 and the second transistor T2 is less than or equal to 0.4 V, and threshold voltages of the first transistor T1 and the second transistor T2 are relatively close, thereby achieving compatibility between the first transistor T1 and the second transistor T2. For example, the absolute value of the difference in threshold voltages between the first transistor T1 and the second transistor T2 is 0.35 V, 0.30 V, 0.28 V, 0.22 V, 0.15 V, etc.

As shown in FIG. 7, the array substrate may include a pixel circuit, and the pixel circuit may include a switching transistor (S-TFT), a drive transistor (D-TFT), and a capacitor (C). The drive transistor (D-TFT) is connected between a power signal line (VDD) and a light-emitting element (EL), a gate of the switching transistor (S-TFT) is connected to a scan signal line (Scan), one of a source and a drain of the switching transistor (S-TFT) is connected to a data signal line (Data), and the other of the source and the drain of the switching transistor (S-TFT) is connected to a gate of the drive transistor (D-TFT). When there are drive signals on both the scan signal line (Scan) and the data signal line (Data), the source and the drain of the switching transistor (S-TFT) are turned on, the gate of the drive transistor (D-TFT) controls a source and a drain of the drive transistor (D-TFT) to be turned on, and the power signal line (VDD) is electrically connected to the light-emitting element (EL), thereby driving the light-emitting element (EL) to emit light.

In some embodiments, when the carrier mobility of the first active portion 210 is less than that of the second active portion 220, that is, the first transistor T1 is a low-mobility transistor and the second transistor T2 is a high-mobility transistor, in one embodiment, the first transistor T1 is the drive transistor (D-TFT) of the pixel circuit, and the second transistor T2 is a transistor of a gate drive circuit or the switching transistor (S-TFT) of the pixel circuit, to meet usage requirements of the array substrate.

In one embodiment, when the carrier mobility of the first active portion 210 is greater than that of the second active portion 220, that is, the second transistor T2 is a low-mobility transistor and the first transistor T1 is a high-mobility transistor, in one embodiment, the second transistor T2 is the drive transistor (D-TFT) of the pixel circuit, and the first transistor T1 is a transistor of a gate drive circuit or the switching transistor (S-TFT) of the pixel circuit, to meet usage requirements of the array substrate.

In some embodiments, in the embodiments described above, each of the first transistor T1 and the second transistor T2 may be a top-gate transistor, that is, the first gate 410 of the first transistor T1 is located on a side of the first active portion 210 facing away from the substrate 100, and the second gate 420 of the second transistor T2 is located on a side of the second active portion 220 facing away from the substrate 100.

In still some embodiments, at least one of the first transistor T1 and the second transistor T2 may alternatively be a dual-gate transistor.

For example, as shown in FIG. 3, the array substrate further includes a third gate 430, and the third gate 430 is located on a side of the first active portion 210 facing the substrate 100. The third gate 430 and the first gate 410 may serve as two gates of the first transistor T1, and the first transistor T1 can become a dual-gate transistor. The third gate 430 can not only assist in controlling an on/off state of the first active portion 210, but also play a role in light shielding, thereby mitigating an impact on the performance of the first active portion 210 due to light incident on the first active portion 210 from the side of the first active portion 210 facing the substrate 100.

In some embodiments, when the first transistor T1 includes the third gate 430, the orthographic projection of the first gate 410 on the substrate 100 is located within an orthographic projection of the third gate 430 on the substrate 100. That is, a distribution area of the first gate 410 may be smaller than that of the third gate 430. The first gate 410 may better assist in controlling the on/off state of the first active portion 210 and be more conducive to light shielding, thereby improving performance of the first transistor T1.

In still some embodiments, the array substrate further includes a fourth gate 440, and the fourth gate 440 is located on the side of the second active portion 220 facing the substrate 100. The fourth gate 440 and the second gate 420 may serve as two gates of the second transistor T2, and the second transistor T2 can become a dual-gate transistor. The fourth gate 440 can not only assist in controlling an on/off state of the second active portion 220, but also play a role in light shielding, thereby mitigating an impact on the performance of the second active portion 220 due to light incident on the second active portion 220 from the side of the second active portion 220 facing the substrate 100.

In some embodiments, when the second transistor T2 includes the fourth gate 440, the orthographic projection of the second gate 420 on the substrate 100 is located within an orthographic projection of the fourth gate 440 on the substrate 100. That is, a distribution area of the second gate 420 may be smaller than that of the fourth gate 440. The second gate 420 may better assist in controlling the on/off state of the second active portion 220 and be more conducive to light shielding, thereby improving performance of the second transistor T2.

In some embodiments, the third gate 430 and the fourth gate 440 may be provided in the same layer and made of the same material, and the third gate 430 and the fourth gate 440 may be prepared and formed in the same process step, thereby simplifying the preparation process of the array substrate.

In some embodiments, the array substrate may include a light-shielding layer, which may also serve as the third gate 430 and/or the fourth gate 440. Thus, the third gate 430 and/or the fourth gate 440 can function as gates of the dual-gate transistor while having a light shielding effect.

In some embodiments, the array substrate further includes a third insulating layer 330 located on a side of the first gate 410 and the second gate 420 facing away from the substrate 100. The first source 510, the first drain 520, the second source 530, and the second drain 540 may be located on a side of the third insulating layer 330 facing away from the substrate 100 to mitigate a problem of short circuits between different electrically conductive layers.

In some embodiments, the first source 510, the first drain 520, the second source 530, and the second drain 540 may be provided in a same layer in order to simplify the structure and preparation process of the array substrate.

In some embodiments, the array substrate further includes a fourth insulating layer 340, and the fourth insulating layer 340 is located between the third gate 430 and the first active portion 210 to prevent the third gate 430 from being in direct contact with the first active portion 210.

As shown in FIG. 1 to FIG. 7, the embodiment of the first aspect of the present application further provides an array substrate. The array substrate includes: a substrate 100; a first semiconductor layer 20a located on one side of the substrate 100, the first semiconductor layer including a first active portion 210; a first insulating layer 310 located on a side of the first semiconductor layer 20a facing away from the substrate 100; a second semiconductor layer 20b located on a side of the first insulating layer 310 facing away from the substrate 100, the second semiconductor layer 20b including a second active portion 220; a first gate 410 located on a side of the first semiconductor layer 20a facing away from the substrate 100, where an orthographic projection of the first gate 410 on the substrate 100 at least partially overlaps an orthographic projection of the first active portion 210 on the substrate 100; and a second gate 420 located on a side of the second semiconductor layer 20b facing away from the substrate 100, where an orthographic projection of the second gate 420 on the substrate 100 at least partially overlaps an orthographic projection of the second active portion 220 on the substrate 100. A material of each of the first active portion 210 and the second active portion 220 includes indium, and an indium content of one of the first active portion 210 and the second active portion 220 is greater than that of the other.

In the array substrate provided in the embodiment of the present application, the array substrate includes the substrate 100, the first semiconductor layer 20a, the first insulating layer 310, the second semiconductor layer 20b, the first gate 410, and the second gate 420. The orthographic projection of the first gate 410 on the substrate 100 at least partially overlaps the orthographic projection of the first active portion 210 of the first semiconductor layer 20a on the substrate 100. The first gate 410 is disposed corresponding to the first active portion 210 to turn on the first active portion 210. Likewise, the second gate 420 is disposed corresponding to the second active portion 220 to turn on the second active portion 220. The material of each of the first active portion 210 and the second active portion 220 includes indium, and the indium content of one of the first active portion 210 and the second active portion 220 is greater than that of the other, and a carrier mobility of one of the first active portion 210 and the second active portion 220 is greater than that of the other. That is, the first active portion 210 and the second active portion 220 have different carrier mobilities. The first insulating layer 310 is disposed between the first semiconductor layer 20a where the first active portion 210 is located and the second semiconductor layer 20b where the second active portion 220 is located, to facilitate adjustment of carrier concentration in the first active portion 210 by using the first insulating layer 310, thereby achieving process compatibility between the first active portion 210 and the second active portion 220, and thus improving process performance of the array substrate.

In some embodiments, the first active portion 210 is provided as a single layer, or the first active portion 210 includes a plurality of first sub-layers 211 that are disposed in a stacked manner, and each of the first sub-layers 211 has an indium content greater than or less than that of the second active portion 220.

A number of the first sub-layers 211 may be configured in various ways. There may be two first sub-layers 211, and the two first sub-layers 211 may have different indium contents to adjust an overall carrier mobility of the first active portion 210 within an appropriate range.

In one embodiment, there may be three first sub-layers 211, and an indium content of the first sub-layer 211 located in the middle is greater than those of the other first sub-layers 211. In this way, the first sub-layer 211 in the middle has the highest carrier mobility, which can enhance transport efficiency of carriers and ensure performance of the first active portion 210.

In some embodiments, when there are three or more first sub-layers 211, and a plurality of first sub-layers 211 may include the first outer edge sub-layer 211a, the first inner edge sub-layer 211b, and the first intermediate sub-layer 211c, and an indium content of each of the first outer edge sub-layer 211a and the first inner edge sub-layer 211b is less than that of the first intermediate sub-layer 211c.

In still some embodiments, there may be four or more first sub-layers 211, and the four or more first sub-layers 211 include the first outer edge sub-layer 211a, the first inner edge sub-layer 211b, and the first intermediate sub-layer 211c, and any of the first sub-layers 211 located between the first outer edge sub-layer 211a and the first inner edge sub-layer 211b may be the first intermediate sub-layer 211c.

In some embodiments, the second active portion 220 is provided as a single layer, or the second active portion 220 includes a plurality of second sub-layers 221 that are disposed in a stacked manner, and each of the second sub-layers 221 has an indium content greater than or less than that of the first active portion 210.

A number of the second sub-layers 221 may be configured in various ways. There may be two second sub-layers 221, and the two second sub-layers 221 may have different indium contents to adjust an overall carrier mobility of the second active portion 220 within an appropriate range.

In one embodiment, there may be three second sub-layers 221, and an indium content of the second sub-layer 221 located in the middle is greater than those of the other second sub-layers 221. In this way, the second sub-layer 221 in the middle has the highest carrier mobility, which can enhance transport efficiency of carriers and ensure performance of the second active portion 220.

In some embodiments, when there are three or more second sub-layers 221, and a plurality of second sub-layers 221 may include the second outer edge sub-layer 221a, the second inner edge sub-layer 221b, and the second intermediate sub-layer 221c, and an indium content of each of the second outer edge sub-layer 221a and the second inner edge sub-layer 221b is less than that of the second intermediate sub-layer 221c.

In still some embodiments, there may be four or more second sub-layers 221, and the four or more second sub-layers 221 include the second outer edge sub-layer 221a, the second inner edge sub-layer 221b, and the second intermediate sub-layer 221c, and any of the second sub-layers 221 located between the second outer edge sub-layer 221a and the second inner edge sub-layer 221b may be the second intermediate sub-layer 221c.

The display panel of the embodiment of the present application and the display panel of any of the embodiments described above may be cross-referenced to each other.

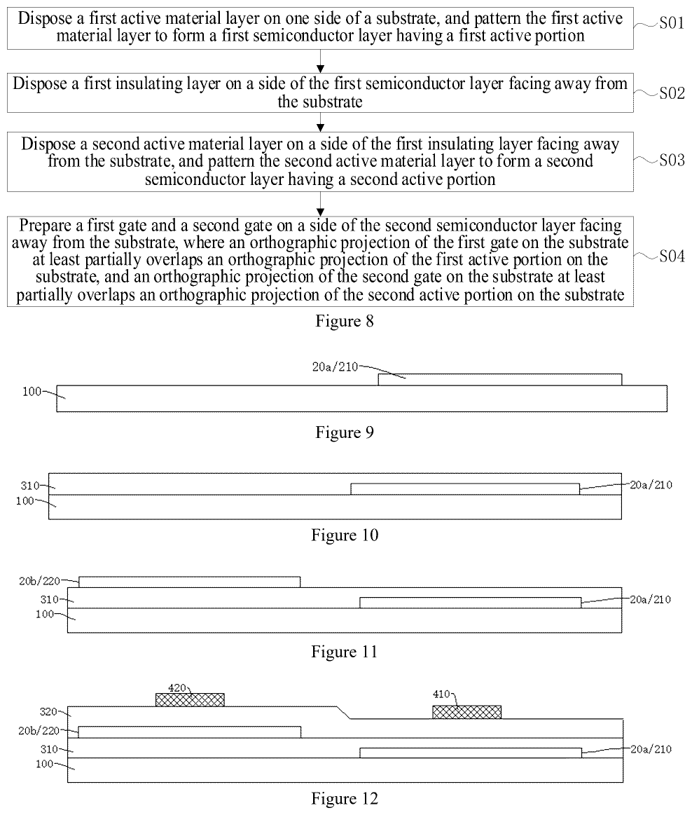

An embodiment in a second aspect of the present application further provides a preparation method for an array substrate. The array substrate may be the array substrate according to any one of the embodiments of the first aspect described above. Referring to FIGS. 1 to 8 together, the preparation method for an array substrate includes the following steps:
step S01: Dispose a first active material layer on one side of a substrate 100, and pattern the first active material layer to form a first semiconductor layer 20a having a first active portion 210, as shown in FIG. 9.
step S02: Dispose a first insulating layer 310 on a side of the first semiconductor layer 20a facing away from the substrate 100, as shown in FIG. 10.
step S03: Dispose a second active material layer on a side of the first insulating layer 310 facing away from the substrate 100, and patterning the second active material layer to form a second semiconductor layer 20b having a second active portion 220, as shown in FIG. 11.
step S04: Prepare a first gate 410 and a second gate 420 on a side of the second semiconductor layer 20b facing away from the substrate, where an orthographic projection of the first gate 410 on the substrate 100 at least partially overlaps an orthographic projection of the first active portion 210 on the substrate 100, and an orthographic projection of the second gate 420 on the substrate 100 at least partially overlaps an orthographic projection of the second active portion 220 on the substrate 100, as shown in FIG. 12.

A carrier mobility of one of the first active portion 210 and the second active portion 220 is greater than that of the other.

In the array substrate prepared according to the embodiments of the present application, the array substrate includes the substrate 100, the first semiconductor layer 20a, the first insulating layer 310, the second semiconductor layer 20b, the first gate 410, and the second gate 420. The orthographic projection of the first gate 410 on the substrate 100 at least partially overlaps the orthographic projection of the first active portion 210 of the first semiconductor layer 20a on the substrate 100. The first gate 410 is disposed corresponding to the first active portion 210 to turn on the first active portion 210. Likewise, the second gate 420 is disposed corresponding to the second active portion 220 to turn on the second active portion 220. The carrier mobility of one of the first active portion 210 and the second active portion 220 is greater than that of the other, that is, the first active portion 210 and the second active portion 220 have different carrier mobilities. Step S02 is provided between step S01 and step S03 to form the first insulating layer 310, to facilitate adjustment of carrier concentration in the first active portion 210 by using the first insulating layer 310, thereby achieving process compatibility between the first active portion 210 and the second active portion 220, and thus improving process performance of the array substrate.

In some embodiments, as shown in FIG. 12, before step S04, the method may further include: preparing a second insulating layer 320 on a side of the second semiconductor layer 20b facing away from the substrate 100. Then, in step S04, the first gate 410 and the second gate 420 may be formed on a side of the second insulating layer 320 facing away from the substrate 100. This improves a problem of short-circuit connection between the second gate 420 and the second active portion 220.

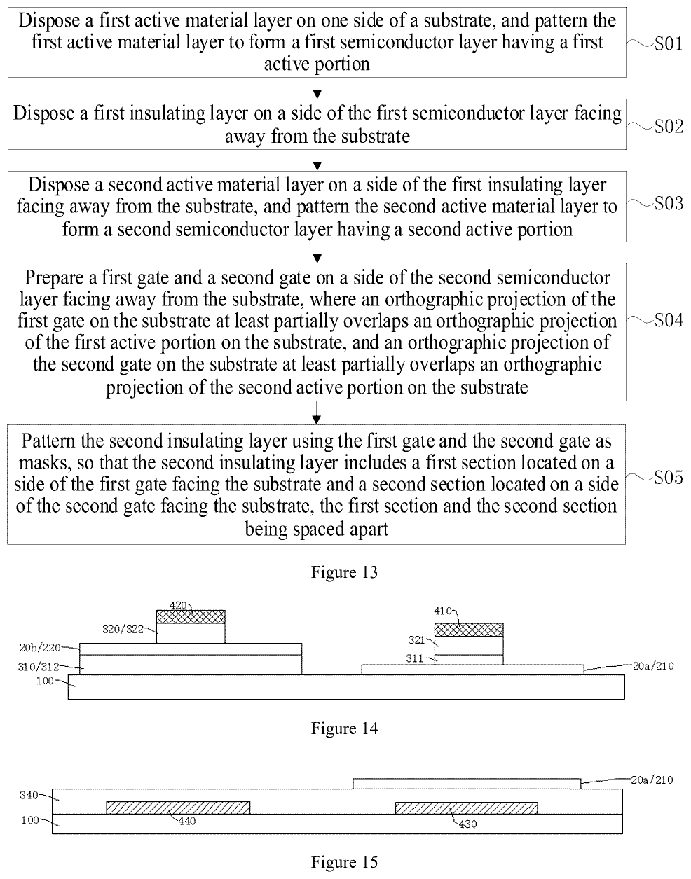

In some embodiments, referring to FIG. 13 together, the preparation method may further include:
step S05: Pattern the second insulating layer 320 using the first gate 410 and the second gate 420 as masks, and the second insulating layer 320 includes a first section 321 located on a side of the first gate 410 facing the substrate 100 and a second section 322 located on a side of the second gate 420 facing the substrate 100, and the first section 321 and the second section 322 are spaced apart, as shown in FIG. 14.

In these embodiments, after the first gate 410 and the second gate 420 are prepared, the second insulating layer 320 may be directly patterned using the first gate 410 and the second gate 420 as masks to form the first section 321 and the second section 322, and an overall distribution area of the second insulating layer 320 can be reduced while simplifying a structure of the array substrate.

In some embodiments, in step S05, as shown in FIG. 14, the first insulating layer 310 is further patterned, and the first insulating layer 310 includes a third section 311 located on a side of the first section 321 facing the substrate 100 and a fourth section 312 located on a side of the second active portion 220 facing the substrate 100, and the third section 311 and the fourth section 312 are spaced apart. The overall distribution area of the second insulating layer 320 can be reduced while simplifying the structure of the array substrate.

In some embodiments, when the array substrate includes a third gate 430 and/or a fourth gate 440, before step S01, the third gate 430 and/or the fourth gate 440 are further prepared on one side of the substrate 100, and a fourth insulating layer 340 is disposed on a side of the third gate 430 and/or the fourth gate 440 facing away from the substrate 100. In step S01, the first semiconductor layer 20a having the first active portion 210 may be prepared on the fourth insulating layer 340.

For example, before step S01, the method further includes: disposing a gate material layer on one side of the substrate 100, and patterning the gate material layer to form a third gate 430, as shown in FIG. 15. In step S01, the first active portion 210 is located on the side of the third gate 430 facing away from the substrate 100.

In some embodiments, when the array substrate includes the fourth insulating layer 340, the first active portion 210 is located on a side of the fourth insulating layer 340 facing away from the substrate 100, and the orthographic projection of the first active portion 210 on the substrate 100 at least partially overlaps an orthographic projection of the third gate 430 on the substrate 100.

And/or, before step S03, the method further includes: disposing a gate material layer on one side of the substrate 100, and patterning the gate material layer to form a fourth gate 440, as shown in FIG. 15. In step S03, the second active portion 220 is located on a side of the fourth gate 440 facing away from the substrate 100.

In some embodiments, when the array substrate includes the fourth insulating layer 340, the second active portion 220 is located on a side of the fourth insulating layer 340 and the first insulating layer 310 facing away from the substrate 100, and the orthographic projection of the second active portion 220 on the substrate 100 at least partially overlaps an orthographic projection of the fourth gate 440 on the substrate 100.

In some embodiments, the third gate 430 and the fourth gate 440 may be prepared and formed in the same process step. For example, before step S01, the method further includes: disposing a gate material layer on one side of the substrate 100, and patterning the gate material layer to form the third gate 430 and the fourth gate 440; and disposing a fourth insulating layer 340 on a side of the third gate 430 and the fourth gate 440 facing away from the substrate 100.

An embodiment of a third aspect of the present application further provides a display panel. The display panel includes the array substrate according to embodiments of the first aspect described above, or the array substrate prepared according to any one of the embodiments of the second aspect described above. The display panel according to the embodiments of the present application may be a liquid crystal display panel, an organic light-emitting diode display panel, or a micro light-emitting diode display panel.

Although the present application is described with reference to some embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the embodiments disclosed herein but includes all the embodiments that fall within the scope of the claims.

What is claimed is:

1. An array substrate, comprising:
a substrate;
a first semiconductor layer located on one side of the substrate, the first semiconductor layer comprising a first active portion;
a first insulating layer located on a side of the first semiconductor layer facing away from the substrate;
a second semiconductor layer located on a side of the first insulating layer facing away from the substrate, the second semiconductor layer comprising a second active portion;
a first gate located on the side of the first semiconductor layer facing away from the substrate, wherein an orthographic projection of the first gate on the substrate at least partially overlaps an orthographic projection of the first active portion on the substrate; and
a second gate located on a side of the second semiconductor layer facing away from the substrate, wherein an orthographic projection of the second gate on the substrate at least partially overlaps an orthographic projection of the second active portion on the substrate,
wherein a carrier mobility of one of the first active portion and the second active portion is greater than a carrier mobility of the other.

2. The array substrate according to claim 1, wherein a thickness of the first insulating layer is 10 nm to 200 nm.

3. The array substrate according to claim 1, wherein a carrier mobility of the first active portion is less than a carrier mobility of the second active portion, and a material of each of the first active portion and the second active portion comprises metal oxide;
the material of the first active portion comprises at least one of indium oxide, gallium oxide, zinc oxide, tin oxide, indium gallium zinc oxide, or indium gallium oxide, wherein a number of indium atoms accounts for 30% to 70% of a total number of metal atoms in the first active portion, a number of gallium atoms accounts for 0 to 70% of the total number of metal atoms in the first active portion, and a number of zinc atoms accounts for 0 to 70% of the total number of metal atoms in the first active portion; a thickness of the first active portion ranges from 3 nm to 100 nm;
the material of the second active portion comprises at least one of indium oxide, gallium oxide, zinc oxide, tin oxide, indium gallium zinc oxide, or indium gallium oxide, wherein a number of indium atoms accounts for 50% to 100% of a total number of metal atoms in the second active portion, a number of gallium atoms accounts for 0 to 50% of the total number of metal atoms in the second active portion, and a number of zinc atoms accounts for 0 to 50% of the total number of metal atoms in the second active portion; a thickness of the second active portion ranges from 3 nm to 100 nm; and
a metallic atomic percentage of indium in the first active portion is less than a metallic atomic percentage of indium in the second active portion.

4. The array substrate according to claim 1, wherein a carrier mobility of the first active portion is greater than a carrier mobility of the second active portion, and a material of each of the first active portion and the second active portion comprises metal oxide;
the material of the second active portion comprises at least one of indium oxide, gallium oxide, zinc oxide, tin oxide, indium gallium zinc oxide, or indium gallium oxide, wherein a number of indium atoms accounts for 30% to 70% of a total number of metal atoms in the first active portion, a number of gallium atoms accounts for 0 to 70% of the total number of metal atoms in the first active portion, and a number of zinc atoms accounts for 0 to 70% of the total number of metal atoms in the first active portion;
a thickness of the second active portion ranges from 3 nm to 100 nm;
the material of the first active portion comprises at least one of indium oxide, gallium oxide, zinc oxide, tin oxide, indium gallium zinc oxide, or indium gallium oxide, wherein a number of indium atoms accounts for 50% to 100% of a total number of metal atoms in the second active portion, a number of gallium atoms accounts for 0 to 50% of the total number of metal atoms in the second active portion, and a number of zinc atoms accounts for 0 to 50% of the total number of metal atoms in the second active portion;
a thickness of the first active portion ranges from 3 nm to 100 nm; and
a metallic atomic percentage of indium in the first active portion is greater than a metallic atomic percentage of indium in the second active portion.

5. The array substrate according to claims 1, further comprising a second insulating layer located on the side of the second semiconductor layer facing away from the substrate, the second gate being located on a side of the second insulating layer facing away from the substrate,
wherein the first insulating layer is in contact with the first active portion and the second active portion; and
the second insulating layer is in contact with the second active portion.

6. The array substrate according to claim 5, wherein the first gate is located on the side of the second insulating layer facing away from the substrate; and
the first gate and the second gate are disposed in a same layer.

7. The array substrate according to claim 6, wherein
the second insulating layer comprises a first section located on a side of the first gate facing the substrate and a second section located on a side of the second gate facing the substrate, the first section and the second section being spaced apart;
an orthographic projection of the first section on the substrate overlaps an orthographic projection of the first gate on the substrate; and
an orthographic projection of the second section on the substrate overlaps an orthographic projection of the second gate on the substrate.

8. The array substrate according to claim 7, wherein the first insulating layer comprises a third section located on a side of the first section facing the substrate and a fourth section located on a side of the second active portion facing the substrate, the third section and the fourth section being spaced apart;
an orthographic projection of the third section on the substrate overlaps the orthographic projection of the first section on the substrate; and
an orthographic projection of the fourth section on the substrate overlaps the orthographic projection of the second active portion on the substrate.

9. The array substrate according to claim 1, wherein the first active portion is provided as a single layer, or the first active portion comprises a plurality of first sub-layers disposed in a stacked manner, and a carrier mobility of each of the first sub-layers is greater than or less than a carrier mobility of the second active portion.

10. The array substrate according to claim 9, wherein the first active portion comprises two first sub-layers, and the two first sub-layers have different carrier mobilities;
or, the first active portion comprises three first sub-layers, and a carrier mobility of the first sub-layer located in the middle is greater than carrier mobilities of the other first sub-layers.

11. The array substrate according to claim 1, wherein the second active portion is provided as a single layer, or the second active portion comprises a plurality of second sub-layers disposed in a stacked manner, and a carrier mobility of each of the second sub-layers is greater than or less than a carrier mobility of the first active portion.

12. The array substrate according to claim 11, wherein the second active portion comprises two second sub-layers, and the two second sub-layers have different carrier mobilities;
or, the second active portion comprises three second sub-layers, and a carrier mobility of the second sub-layer located in the middle is greater than carrier mobilities of the other second sub-layers.

13. The array substrate according to claim 1, further comprising a first source and a first drain, wherein the first active portion comprises a first source region and a first drain region, the first source is electrically connected to the first source region, the first drain is electrically connected to the first drain region, and the first source, the first drain, the first gate, and the first active portion together form a first transistor; and
a second source and a second drain, wherein the second active portion comprises a second source region and a second drain region, the second source is electrically connected to the second source region, the second drain is electrically connected to the second drain region, and the second source, the second drain, the second gate, and the second active portion together form a second transistor;
wherein an absolute value of a difference in threshold voltages between the first transistor and the second transistor is less than or equal to 0.4 V.

14. The array substrate according to claim 13, wherein a carrier mobility of the first active portion is less than a carrier mobility of the second active portion, the first transistor is a drive transistor of a pixel circuit, and the second transistor is a transistor of a gate drive circuit or a switching transistor of the pixel circuit;
or, the carrier mobility of the first active portion is greater than the carrier mobility of the second active portion, the first transistor is a transistor of a gate drive circuit or a switching transistor of a pixel circuit, and the second transistor is a drive transistor of the pixel circuit.

15. The array substrate according to claim 1, further comprising: a third gate located on a side of the first active portion facing the substrate,
wherein the orthographic projection of the first gate on the substrate is located within an orthographic projection of the third gate on the substrate;
a fourth gate located on a side of the second active portion facing the substrate, wherein the orthographic projection of the second gate on the substrate is located within an orthographic projection of the fourth gate on the substrate; and
a light-shielding layer serves as the third gate or the fourth gate.

16. A preparation method for an array substrate, comprising:
disposing a first active material layer on one side of a substrate, and patterning the first active material layer to form a first semiconductor layer having a first active portion; disposing a first insulating layer on a side of the first semiconductor layer facing away from the substrate;
disposing a second active material layer on a side of the first insulating layer facing away from the substrate, and patterning the second active material layer to form a second semiconductor layer having a second active portion; and
preparing a first gate and a second gate on a side of the second semiconductor layer facing away from the substrate, wherein an orthographic projection of the first gate on the substrate at least partially overlaps an orthographic projection of the first active portion on the substrate, and an orthographic projection of the second gate on the substrate at least partially overlaps an orthographic projection of the second active portion on the substrate,
wherein a carrier mobility of one of the first active portion and the second active portion is greater than a carrier mobility of the other.

17. The preparation method according to claim 16, wherein before the step of preparing a first gate and a second gate on a side of the second semiconductor layer facing away from the substrate, the method further comprises:
preparing a second insulating layer on the side of the second semiconductor layer facing away from the substrate,
wherein in the step of preparing a first gate and a second gate on a side of the second semiconductor layer facing away from the substrate, the first gate and the second gate are prepared on a side of the second insulating layer facing away from the substrate.

18. The preparation method according to claim 17, further comprising:
patterning the second insulating layer using the first gate and the second gate as masks, the second insulating layer comprising a first section located on a side of the first gate facing the substrate and a second section located on a side of the second gate facing the substrate, the first section and the second section being spaced apart,
wherein in the step of patterning the second insulating layer using the first gate and the second gate as masks, the first insulating layer is further patterned, the first insulating layer comprising a third section located on a side of the first section facing the substrate and a fourth section located on a side of the second active portion facing the substrate, the third section and the fourth section being spaced apart.

19. The preparation method according to claim 16, wherein before the step of disposing a first active material layer on one side of a substrate, and patterning the first active material layer to form a first semiconductor layer having a first active portion, the method further comprises:
disposing a gate material layer on one side of the substrate, and patterning the gate material layer to form a third gate,
wherein in the step of disposing a first active material layer on one side of a substrate, and patterning the first active material layer to form a first semiconductor layer having a first active portion, the first active portion is located on a side of the third gate facing away from the substrate;
and, before the step of disposing a second active material layer on a side of the first insulating layer facing away from the substrate, and patterning the second active material layer to form a second semiconductor layer having a second active portion, the method further comprises:
disposing a gate material layer on one side of the substrate, and patterning the gate material layer to form a fourth gate,
wherein in the step of disposing a second active material layer on a side of the first insulating layer facing away from the substrate, and patterning the second active material layer to form a second semiconductor layer having a second active portion, the second active portion is located on a side of the fourth gate facing away from the substrate.

20. A display panel, comprising:
an array substrate, comprising:
a substrate;
a first semiconductor layer located on one side of the substrate, the first semiconductor layer comprising a first active portion;
a first insulating layer located on a side of the first semiconductor layer facing away from the substrate;
a second semiconductor layer located on a side of the first insulating layer facing away from the substrate, the second semiconductor layer comprising a second active portion;
a first gate located on the side of the first semiconductor layer facing away from the substrate, wherein an orthographic projection of the first gate on the substrate at least partially overlaps an orthographic projection of the first active portion on the substrate; and
a second gate located on a side of the second semiconductor layer facing away from the substrate, wherein an orthographic projection of the second gate on the substrate at least partially overlaps an orthographic projection of the second active portion on the substrate,
wherein a carrier mobility of one of the first active portion and the second active portion is greater than a carrier mobility of the other.
